(19) United States
(12) Patent Application Publication
(10) Pub. No.: US 2009/0237609 A1
(43) Pub. Date: Sep. 24, 2009

(54) Display Device

(76) Inventor: Woo-Jae Lee, Yongin-si (KR)

Correspondence Address: Frank Chau, Esq.;F. CHAU & ASSOCIATES, LLC, 130 Woodbury Road, Woodbury, NY, 11797, US

(21) Appl. No.: 12/392,296

(22) Filed: Feb. 25, 2009

(30) Foreign Application Priority Data
Mar. 20, 2008 (KR) 10-2008-0025936

(51) Int. Cl. G02F 1/1333; H01L 27/12; H01J 1/66

(52) U.S. Cl. 349/158; 257/59; 313/498

(57) ABSTRACT

A liquid crystal display device includes a first panel including a first substrate and a first plurality of thin film elements formed thereon, a second panel including a second substrate and a second plurality of thin film elements formed thereon, and a liquid crystal layer disposed the lower panel and the upper panel. The first substrate and the second substrate each include alkali-containing glass.

### CROSS-REFERENCE TO RELATED APPLICATION

This application claims priority to and the benefit of Korean Patent Application No. 10-2008-0025936 filed in the Korean Intellectual Property Office on Mar. 20, 2008, the entire contents of which are incorporated herein by reference.

### BACKGROUND OF THE INVENTION

(a) Technical Field

The present invention relates to a display device, and more particularly, the present invention relates to the display device using a soda lime glass substrate.

(b) Description of the Related Art

Recently, flat panel display devices have gained acceptance in the market place. A flat panel display is a display device with a small thickness relative to the size of the screen. Examples of flat panel displays include liquid crystal displays (LCD), plasma display panels (PDP), organic light emitting devices (OLED), and electrophoretic displays (EPD).

The liquid crystal display (LCD) is the most commonly used flat panel display device. The LCD includes two substrates with electrodes formed thereon and a liquid crystal layer interposed between the two substrates. In the LCD, a voltage is applied to the electrodes to rearrange liquid crystal molecules of the liquid crystal layer to thereby control the transmittance of light passing through the liquid crystal layer. The PDP is a display device for displaying images by using plasma generated by gas discharge. The electrophoretic display is a display device utilizing the electrophoretic phenomenon to repeatedly write or erase information made of symbols such as characters and numbers. In the OLED, electrons and holes are injected into an organic illumination layer respectively from a cathode (electron injection electrode) and an anode (hole injection electrode). The injected electrons and holes are combined to generate excitons, which illuminate when converting from an excited state to a ground state. The organic light emitting display is remarkably thin and surpasses the liquid crystal display in terms of display quality, high response speed, and contrast ratio. Accordingly, the organic light emitting display is often spotlighted as a next-generation display device.

These display devices generally include an insulating substrate and a plurality of thin film elements formed thereon. The insulating substrate may be made of a transparent material such as glass. A glass substrate may be a non-alkali-containing glass substrate that does not contain an alkali component or an alkali-containing glass substrate that contains an alkali component.

### SUMMARY OF THE INVENTION

A non-alkali-containing glass substrate has a high melting point of 1700° C. Non-alkali-containing glass substrates may be manufactured by a fusion process and in this process, lateral sides of the glass are cooled by air. The fusion process used to manufacture these substrates may be expensive. Since an alkali-containing glass substrate can be manufactured at a relative low melting temperature, the manufacturing cost can be reduced compared to the non-alkali-containing glass substrate. However, an alkali component contained in the alkali-containing substrate may be prone to melting during follow-up processes, thereby affecting stability of thin film elements thereof.

Exemplary embodiments of the present invention seek to reduce the cost of manufacturing alkali-containing substrates used in flat panels while obtaining stable thin film elements.

A display device according to an exemplary embodiment of the present invention includes an alkali-containing glass substrate, a transparent organic layer contacting the glass substrate, and a plurality of thin film elements formed on the transparent organic layer.

The glass substrate may be a soda lime glass substrate. The transparent organic layer may have a same transparency as the glass substrate and a refractive index in a range of about 1.5 to about 1.6. The transparent organic layer may have a glass transition temperature of about 250° C. to about 450° C. The transparent organic layer may be made of polyimide. The thickness of the transparent organic layer may be in a range of about 0.3 μm to 50 μm. The sheet resistance of the transparent organic layer may be less than 2×10¹⁷ Ωcm. The thin film elements may include a thin film transistor. The thin film elements may further include an organic light emitting element.

The display device may further include a liquid crystal layer formed on the thin film elements. The display device may further include an electrophoretic active layer formed on the thin film elements. The thin film elements may include a color filter.

A liquid crystal display device according to another exemplary embodiment of the present invention includes a first panel including a first substrate having pixel electrodes, thin film transistors and signal lines thereon, a second panel including a second substrate having a common electrode, at least one color filter, and at least one light blocking member, and a liquid crystal layer disposed between the first panel and the second panel, wherein at least one of the first and the second substrates is an alkali-containing glass substrate, and the at least one alkali-containing glass substrate has a transparent organic layer contacting therewith.

The alkali-containing glass substrate is a soda lime glass substrate. The transparent organic layer has a same transparency as the alkali-containing glass substrate and a refractive index in a range of about 1.5 to about 1.6. The transparent organic layer has a glass transition temperature of about 250° C. to about 450° C. The organic layer includes polyimide. The thickness of the transparent organic layer is in a range of about 0.3 μm to about 50 μm. The sheet resistance of the organic layer is less than about 2×10¹⁷ Ωcm.

An organic light emitting device according to another exemplary embodiment of the present invention includes a first substrate including alkali-containing glass, and a transparent organic layer including polyimide formed on the substrate, wherein the transparent organic layer has the same transparency as the first substrate, and a refractive index in a range of about 1.5 to about 1.6.

The transparent organic layer has a glass transition temperature T_{g} of about 250° C. to about 450° C. The thickness of the organic layer is in a range of about 0.3 μm to about 50 μm. The sheet resistance of the transparent organic layer is in a range of about 1×10¹⁷ Ωcm to about 2×10¹⁷ Ωcm.

According to an exemplary embodiment of the present invention, the substrate of the display device uses an inexpensive alkali-containing glass substrate such that the manufacturing cost of the display device may be reduced. Also, transparent polyimide is formed on the alkali-containing glass substrate such that the manufacturing defect rate of the thin film elements may be reduced. Furthermore, the transparent polyimide is used as an alignment material in the manufacturing process of the display device such that the process for forming it on the alkali-containing glass substrate may be simply and easily executed.

### BRIEF DESCRIPTION OF THE DRAWINGS

The above and other features and aspects of the exemplary embodiments of the present invention will be described in detail with reference to the accompanying drawings, in which:

FIG. 1 is a perspective view of a liquid crystal display according to an exemplary embodiment of the present invention;

FIG. 2 is a cross-sectional view of the liquid crystal display shown in FIG. 1 taken along the line II-II;

FIG. 3 is a layout view of an organic light emitting device according to an exemplary embodiment of the present invention;

FIG. 4 is a cross-sectional view of the organic light emitting device shown in FIG. 3 taken along the line IV-IV;

FIG. 5 is a cross-sectional view of an electrophoretic display according to an exemplary embodiment of the present invention; and

FIG. 6 is a graph showing an operation result of the thin film transistor according to existence and nonexistence of a transparent organic layer on a substrate.

### DETAILED DESCRIPTION OF EXEMPLARY EMBODIMENTS

Exemplary embodiments of the present invention will be described more fully hereinafter with reference to the accompanying drawings. As those skilled in the art would realize, the described exemplary embodiments may be modified in various different ways, all without departing from the spirit or scope of the present invention.

In the drawings, the thickness of layers, films, panels, regions, etc., may be exaggerated for clarity. Like reference numerals may designate like elements throughout the specification. It will be understood that when an element such as a layer, film, region, or substrate is referred to as being “on” another element, it can be directly on the other element or intervening elements may also be present.

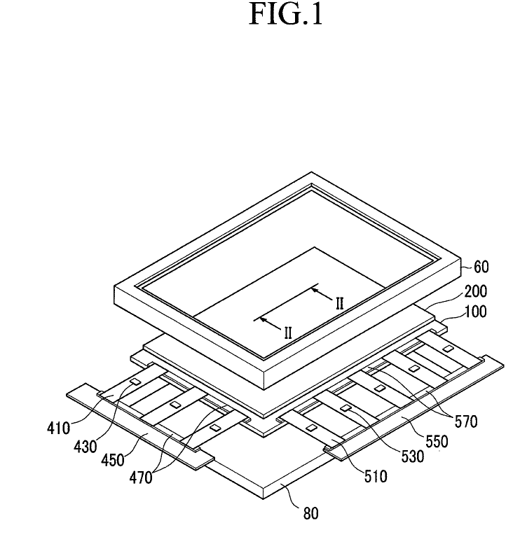

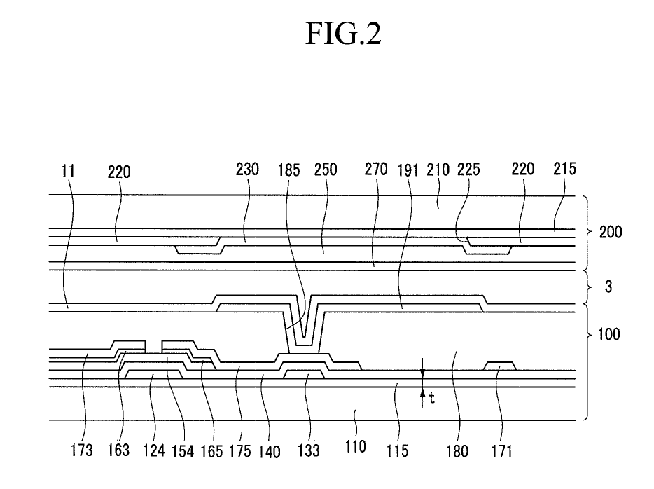

A liquid crystal display according to an exemplary embodiment of the present invention will be described in detail with reference to FIG. 1 and FIG. 2.

FIG. 1 is a perspective view of a liquid crystal display according to an exemplary embodiment of the present invention, and FIG. 2 is a cross-sectional view of the liquid crystal display shown in FIG. 1 taken along the line II-II.

Referring to FIG. 1, a liquid crystal display includes a lower panel 100, an upper panel 200, and a liquid crystal layer 3 formed between the lower panel 100 and the upper panel 200.

The lower panel 100 includes a substrate and a plurality of thin film elements formed thereon. The substrate is made of soda lime glass. The thin film elements include transparent organic layers, pixel electrodes, thin film transistors, and various signal lines.

The upper panel 200 faces the lower panel 100, and is smaller than the lower panel 100 such that a portion of the edge of the lower panel 100 is not covered by the upper panel 200 and is exposed by the upper panel 200. The upper panel 200 includes a substrate and a plurality of thin film elements. The substrate is made of soda lime glass. The thin film elements include a transparent organic layer, a common electrode, color filters, and a light blocking member.

The liquid crystal display also includes flexible printed circuit films 410 and 510, IC chips 430 and 530, printed circuit boards (PCBs) 450 and 550, and conductive adhesives 470 and 570.

One end of each of the flexible printed circuit films 410 and 510 is attached to the exposed edge of the lower panel 100 through the conductive adhesives 470 and 570, and the other ends thereof are attached to the printed circuit boards (PCB) 450 and 550 as a signal supply through the conductive adhesives 470 and 570, respectively. The IC chip 430 and 530 (TCP type) are formed on the flexible printed circuit films 410 and 510. The flexible printed circuit films 410 and 510 may be bent, and the printed circuit boards (PCB) 450 and 550 are disposed under the lower panel 100 (a bent TCP). Alternatively, the flexible printed circuit films 410 and 510 may be straight, and may be disposed in parallel (a flat TCP). The IC chips 430 and 530 may be directly mounted on the lower panel 100 (COG/FOG type).

A lighting unit 80 is disposed under the lower panel 100, and a cover 60 is disposed on the upper panel 200. The lower panel 100 and the upper panel 200 may be stably fixed to the lighting unit 80 through the cover 60.

A detailed structure of the lower panel 100 and the upper panel 200 will be described with reference to FIG. 2.

A transparent organic layer 115 is formed on a lower substrate 110. The lower substrate 110 is made of an inexpensive soda lime glass. The transparent organic layer 115 is made of a polyimide, and contacts the lower substrate 110. The transparent organic layer 115 may have the same transparency as the glass of the display panels 100 and 200. The transparent organic layer 115 may have a transition temperature T_{g} of about 250° C. to about 450° C. Accordingly, the transparent organic layer 115 may be used in the high temperature process. The thermal expansion coefficient of the glass is in a range of about 3 ppm to about 80 ppm. The refractive index of the transparent organic layer 115 is in a range of about 1.5 to about 1.6, the sheet resistance thereof is in a range of about 1×10¹⁷ Ωcm to about 2×10¹⁷ Ωcm, the dielectric constant thereof is in a range of about 2.5 MHz to about 3.5 MHz, and the Young's modulus thereof is in a range of about 1.5 GPa to about 5 GPa. In general, an organic layer made of a polyimide may have a glass transition temperature of about 350° C. to about 550° C.

The transparent organic layer 115 may be formed on the lower substrate 110 through spin coating, slit coating, spin and slit coating, slot dying, or gravure printing, and may be hardened in a range of temperatures form about 150° C. to about 250° C. In this way, the transparent organic layer 115 may completely cover impurities that exist on the lower substrate 110. Accordingly, the impurities and the alkali components that exist in the lower substrate 110 do not influence the thin film elements.

The thickness t of the transparent organic layer 115 may be in a range of about 0.3 μm to about 50 μm. When the thickness t of the transparent organic layer 115 is less than about 0.3 μm, it is difficult to uniformly form the transparent organic layer 115 on the lower substrate 110, and the transparent organic layer 115 may not cover the impurities on the lower substrate 110 such that many defects may be generated during the manufacture of the display device. When the thickness t of the transparent organic layer 115 is more than about 50 μm, the transmittance is reduced and the transparent organic layer 115 may be bent during hardening. Furthermore, it is difficult to thickly form the transparent organic layer 115, and when the thickness is increased, further advantageous effects are not generated.

A gate conductor including a plurality of gate lines (not shown) and a plurality of storage electrodes 133 are formed on the transparent organic layer 115. The gate lines transmit gate signals and include a plurality of gate electrodes 124 and end portions (not shown) having a wide area for connection with a different layer or the IC chip 430. The storage electrodes 133 are separated from the gate lines.

A gate insulating layer 140, a plurality of semiconductors 154, a plurality of ohmic contacts 163 and 165, a plurality of data lines 171, and a plurality of drain electrodes 175 are sequentially formed on the gate conductor.

The data lines 171 transmit data signals, and include a plurality of source electrodes 173 extending toward the gate electrodes 124 and end portions (not shown) having a wide area for connection with a different layer or the IC chip 530. The drain electrodes 175 are separated from the data lines 171 and are opposite to the source electrodes 173 with reference to the gate electrodes 124.

A gate electrode 124, a source electrode 173, and a drain electrode 175 form a thin film transistor (TFT) together with a semiconductor 154, and a channel of the TFT is formed in the semiconductor 154 between the source electrode 173 and the drain electrode 175.

The ohmic contacts 163 and 165 are interposed only between the semiconductors 154 therebelow and the data lines 171 and drain electrodes 175 thereabove and the contact resistance between them is reduced. The semiconductors 154 have exposed portions that are not covered by the source electrodes 173 and the drain electrodes 175.

A passivation layer 180 is formed on the exposed semiconductors 154, the data lines 171, the drain electrodes 175, and the gate insulating layer 140.

The passivation layer 180 has a plurality of contact holes 185 exposing the drain electrodes 175. The passivation layer 180 and the gate insulating layer 140 have a plurality of contact holes (not shown) respectively exposing the end portions of the gate lines and the data lines 171.

A plurality of pixel electrodes 191 are formed on the passivation layer 180. The pixel electrodes 191 may be made of a transparent conductive material such as indium tin oxide (ITO) or indium zinc oxide (IZO).

The pixel electrodes 191 are connected to the drain electrodes 175 through the contact holes 185, and receive data voltages from the drain electrodes 175.

A plurality of contact assistants may be formed on the passivation layer 180. The contact assistants are respectively connected to the end portions of the gate lines and the data lines 171 through the contact holes.

An alignment layer 11 is formed on the pixel electrodes 191. The alignment layer 11 may be made of an organic material or an inorganic material, for example, a polyimide may be used.

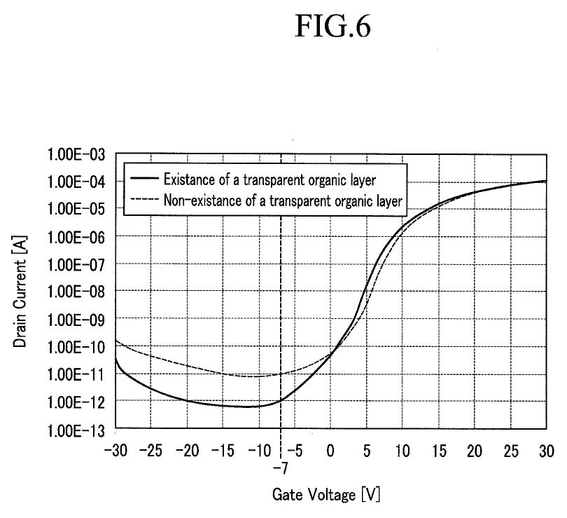

The thin film elements such as the above-described thin film transistors are formed on the transparent organic layer 115 such that operational defects due to the alkali components and the impurities included in the lower substrate 110 are not generated. Furthermore, the transparent organic layer 115 may be formed on the lower substrate 110. FIG. 6 is a graph showing an operation result of the thin film transistor according to existence and nonexistence a transparent organic layer 115 on the lower substrate 110. The solid line in the graph shows the operation result when the transparent organic layer 115 exists on the lower substrate 110 made of a soda lime glass, and the dotted line shows the operation result when the transparent organic layer 115 does not exist on the lower substrate 110. As shown in FIG. 6, under an off current (a reference to the gate voltage of −7V), the drain current is 1×10⁻¹¹ A in the case that the transparent organic layer 115 does not exist, and the drain current is 1×10⁻¹² A in the case that the transparent organic layer 115 exists. Under an on current (a reference to the gate voltage of 20V), the drain current has similar values whether the transparent organic layer 115 exists or not. Accordingly, the characteristics of the thin film transistor may benefit from the inclusion of the transparent organic layer 115.

A transparent organic layer 215 is also formed on an upper substrate 210. The upper substrate 210 is made of a soda lime glass like the lower substrate 110. The transparent organic layer 215 is made of a polyimide, and contacts the upper substrate 210. The transparent organic layer 215 may have the same transparency as the glass. The transparent organic layer 215 may have a transition temperature T_{g} of about 250° C. to about 450° C. Accordingly, the transparent organic layer 215 may be used in the high temperature process. The thermal expansion coefficient of the glass is in a range of about 3 ppm to about 80 ppm. The refractive index of the transparent organic layer 215 is in a range of about 1.5 to about 1.6, the sheet resistance thereof is in a range of about 1×10¹⁷ Ωcm to about 2×10¹⁷ Ωcm, the dielectric constant thereof is in a range of about 2.5 MHz to about 3.5 MHz, and the Young's modulus thereof is in a range of about 1.5 GPa to about 5 GPa. In general, an organic layer made of a polyimide may have a glass transition temperature of about 350° C. to about 550° C.

The transparent organic layer 215 may be formed on the upper substrate 210 through spin coating, slit coating, spin and slit coating, slot dying, or gravure printing, and may be hardened within a temperature range of about 150° C. to about 250° C. In this way, the transparent organic layer 215 may completely cover impurities that exist on the upper substrate 210. Accordingly, the impurities and the alkali components that exist in the upper substrate 210 do not influence the thin film elements.

The thickness t of the transparent organic layer 215 may be in a range of about 0.3 μm to about 50 μm. When the thickness t of the transparent organic layer 215 is less than about 0.3 μm, it is difficult to uniformly form the transparent organic layer 215 on the upper substrate 210, and the transparent organic layer 215 may not completely cover the impurities on the upper substrate 210 such that many defects may be generated during the manufacture of the display device. When the thickness t of the transparent organic layer 215 is more than about 50 μm, the transmittance is reduced and the transparent organic layer 215 may be bent during hardening. Furthermore, it is difficult to thickly form the transparent organic layer 215, and when the thickness is increased, further advantageous effects are not generated.

A light blocking member 220 is formed on the transparent organic layer 215. The light blocking member 220 includes a plurality of openings 225 facing the pixel electrodes 191 and having almost the same shape as the pixel electrodes 191, thereby preventing light leakage between the pixel electrodes 191.

An overcoat 250 is formed on the upper substrate 210 and the light blocking member 220. The overcoat 250 may be made of an insulating material, and provides a flat surface. The overcoat 250 may be omitted.

A common electrode 270 is formed on the overcoat 250, and the common electrode 270 is made of a transparent conductor such as ITO and IZO. A plurality of color filters 230 are formed between the transparent organic layer 215 and the overcoat 250, and the overcoat 250 prevents the color filters 230 from being exposed. Each color filter 230 is at least partially in an opening 225 of the light blocking member 220, and may display a primary color such as three primary colors of red, green, and blue.

A liquid crystal layer 3 is formed between the upper panel 200 and the lower panel 100.

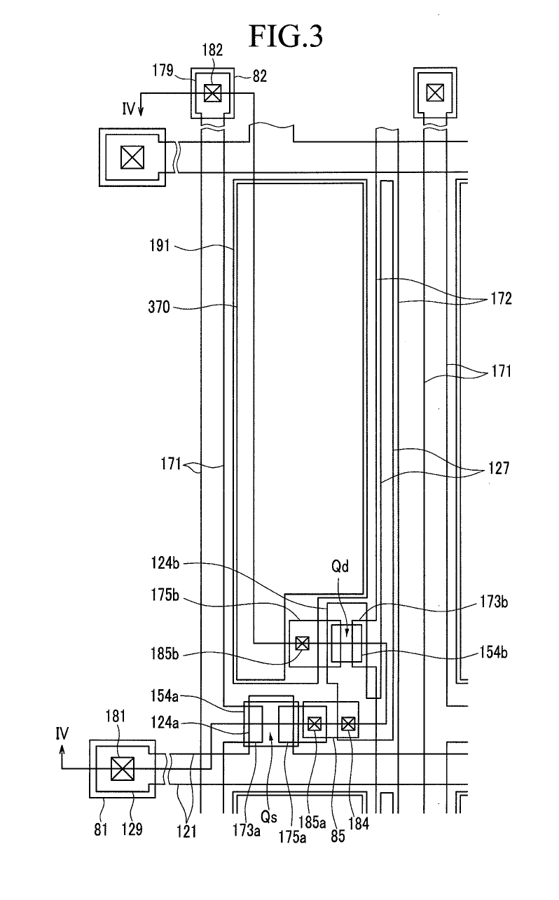

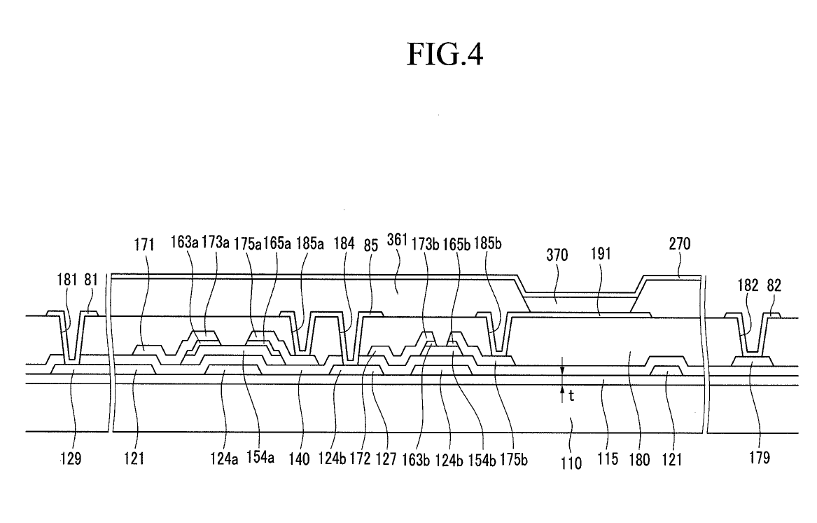

Next, an organic light emitting device according to an exemplary embodiment of the present invention will be described with reference to FIG. 3 and FIG. 4.

FIG. 3 is a layout view of an organic light emitting device according to an exemplary embodiment of the present invention, and FIG. 4 is a cross-sectional view of the organic light emitting device shown in FIG. 3 taken along the line IV-IV.

A transparent organic layer 115 is formed on a substrate 110. The substrate 110 is made of a soda lime glass. The transparent organic layer 115 is made of a polyimide and contacts the substrate 110. The transparent organic layer 115 may have the same transparency as the glass. The transparent organic layer 115 may have a glass transition temperature T_{g} of about 250° C. to about 450° C. and it may be used in the high temperature process. The thermal expansion coefficient of the glass is in a range of about 3 ppm to about 80 ppm. Also, the refractive index of the transparent organic layer 115 is in a range of about 1.5 to about 1.6, the sheet resistance thereof is in a range of about 1×10¹⁷ Ωcm to about 2×10¹⁷ Ωcm, the dielectric constant thereof is in a range of about 2.5 MHz to about 3.5 MHz, and the Young's modulus thereof is in a range of about 1.5 GPa to about 5 GPa.

In general, an organic layer made of a polyimide may have a glass transition temperature of about 350° C. to about 550° C.

The transparent organic layer 115 may be formed on the substrate 110 through spin coating, slit coating, spin and slit coating, slot dying, or gravure printing, and may be hardened by a temperature in a range of about 150° C. to about 250° C. In this way, the transparent organic layer 115 may completely cover the impurities that exist on the substrate 110. Accordingly, the impurities and the alkali components that exist in the substrate 110 do not influence the thin film elements.

The thickness t of the transparent organic layer 115 may be in a range of about 0.3 μm to about 50 μm. When the thickness t of the transparent organic layer 115 is less than about 0.3 μm, it may be difficult to uniformly form the transparent organic layer 115 on the substrate 110, and the transparent organic layer 115 may not cover the impurities on the substrate 110 and defects may be generated during the manufacture of the display device. When the thickness t of the transparent organic layer 115 is more than about 50 μm, the transmittance is reduced and the transparent organic layer 115 may bend during hardening. Furthermore, it may be difficult to thickly form the transparent organic layer 115, and when the thickness is increased, further advantageous effects are not generated.

A plurality of gate conductors including a plurality of gate lines 121 including first control electrodes 124a and a plurality of second control electrodes 124b are formed on the transparent organic layer 115.

The gate lines 121 transmit gate signals and are substantially extended in the transverse direction. Each gate line 121 includes an end portion 129 having a large area for contact with another layer or an external driving circuit and the first control electrodes 124a that are extended from the gate lines 121. The second control electrodes 124b are separated from the gate lines 121 including a storage electrode 127 extending in one direction.

A gate insulating layer 140 including a silicon nitride (SiNx) and/r silicon oxide (SiO2) is formed on the gate conductors 121, 124a, 124b, and 127.

A plurality of first semiconductors 154a and a plurality of second semiconductors 154b, for example, including hydrogenated amorphous silicon and/or polysilicon are formed on the gate insulating layer 140. The first semiconductors 154a overlap the first control electrodes 124a and the second semiconductors 154b overlap the second control electrodes 124b.

A plurality of first ohmic contacts 163a and 165a and a plurality of second ohmic contacts 163b and 165b are respectively formed on the first and second semiconductors 154a and 154b. The first ohmic contacts 163a and 165a are disposed as a pair on the first semiconductors 154a, and the second ohmic contacts 163b and 165b are disposed as a pair on the second semiconductors 154b.

A plurality of data conductors including a plurality of data lines 171, a plurality of driving voltage lines 172, and a plurality of first and second output electrodes 175a and 175b are formed on the ohmic contacts 163a, 163b, 165a, and 165b and the gate insulating layer 140.

The data lines 171 transmitting data signals extend substantially in the longitudinal direction and intersect the gate lines 121. Each data line 171 includes a plurality of first input electrodes 173a extended toward the first control electrodes 124a and an end portion 179 having a large area for contact with another layer or an external driving circuit.

The driving voltage lines 172 for transmitting driving voltages extend substantially in the longitudinal directional, and intersect the gate lines 121. Each of the driving voltage lines 172 includes a plurality of second input electrodes 173b extending toward the second control electrodes 124b, and portions overlapping the storage electrodes 127.

The first and second output electrodes 175a and 175b are separated from each other, as well as from the data lines 171 and the driving voltage lines 172. The first input electrode 173a and the first output electrode 175a are opposite to each other with respect to the first control electrode 124a. The second input electrode 173b and the second output electrode 175b are opposite to each other with respect to the second control electrode 124b.

A passivation layer 180 is formed on the data conductors 171, 172, 175a, and 175b and the exposed semiconductors 154a and 154b. The passivation layer 180 may be made of an inorganic insulator or an organic insulator and may have a flat surface.

The passivation layer 180 has a plurality of contact holes 182, 185a, 185b respectively exposing the end portions of the data lines 171 and the first and the second output electrodes 175a and 175b. The passivation layer 180 and the gate insulating layer 140 have a plurality of contact holes 181 and 184 respectively exposing the end portions 129 of the gate lines 121 and the second control electrodes 124b.

A plurality of pixel electrodes 191, a plurality of connecting members 85, and a plurality of contact assistants 81 and 82 are formed on the passivation layer 180. The connecting members 85 are respectively connected to the second control electrodes 124b and the first output electrodes 175a through the contact holes 184 and 185a. The contact assistants 81 and 82 are connected to the end portions 129 of the gate lines 121 and the end portions 179 of the data lines 171 through the contact holes 181 and 182, respectively.

A partition 361 is formed on the passivation layer 180. The partition 361 surrounds the edges of the pixel electrodes 191 and is made of an organic insulator and/or an inorganic insulator. The partition 361 may be made of a photosensitive material including black pigments, and the partition 361 functions as a light blocking member in this case.

A plurality of organic light emitting members 370 are formed on the pixel electrodes 191 and a common electrode 270 is formed on the organic light emitting members 370. An encapsulation layer (not shown) may be formed on the common electrode 270. The encapsulation layer encapsulates the organic light emitting members 370 and common electrode 270 and blocks moisture and/or oxides from penetrating from the outside.

The thin film elements such as the above-described thin film transistors are formed on the transparent organic layer 115 and operational defects due to the alkali components and the impurities included in the lower substrate 110 may be avoided.

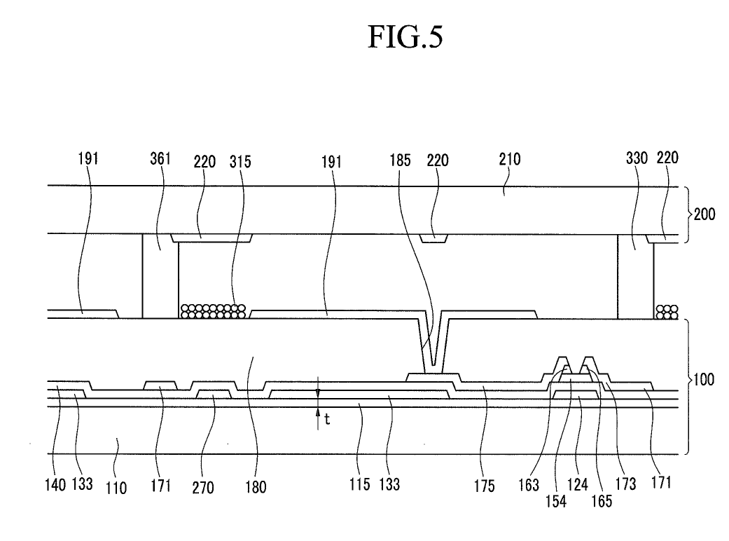

Next, an electrophoretic display according to an exemplary embodiment of the present invention will be described in detail with reference to FIG. 5.

FIG. 5 is a cross-sectional view of an electrophoretic display according to an current exemplary embodiment of the present invention.

Referring to FIG. 5, an electrophoretic display includes a lower panel 100, an upper panel 200, a plurality of partitions 361, and electrophoretic particles 315.

In the lower panel 100, a transparent organic layer 115 is formed on the lower substrate 110. The lower substrate 110 is made of a soda lime glass. The transparent organic layer 115 is made of a polyimide, and contacts the lower substrate 110. The transparent organic layer 115 may have the same transparency as the glass. The transparent organic layer 115 may have a glass transition temperature of about 250° C. to about 450° C. such that it may be used in a high temperature process, and the thermal expansion coefficient thereof is in a range of about 3 ppm to about 80 ppm. Also, the refractive index of the transparent organic layer 115 is in a range of about 1.5 to about 1.6, the sheet resistance thereof is in a range of about 1×10¹⁷ Ωcm to about 2×10¹⁷ Ωcm, the dielectric constant thereof is in a range of about 2.5 MHz to about 3.5 MHz, and the Young's modulus thereof is in a range of about 1.5 GPa to about 5 GPa.

In general, an organic layer made of a polyimide may have a glass transition temperature of about 350° C. to about 550° C.

The transparent organic layer 115 may be formed on the lower substrate 110 through spin coating, slit coating, spin and slit coating, slot dying, or gravure printing, and may be hardened in a temperature range of about 150° C. to about 250° C. In this way, the transparent organic layer 115 may completely cover the impurities that exist on the lower substrate 110. Accordingly, the impurities and the alkali components that exist in the lower substrate 110 do not influence the other thin film elements.

The thickness t of the transparent organic layer 115 may be in a range of about 0.3 μm to about 50 μm. When the thickness t of the transparent organic layer 115 is less than about 0.3 μm, it may be difficult to uniformly form the transparent organic layer 115 on the lower substrate 110, and the transparent organic layer 115 may not cover the impurities on the lower substrate 110. Accordingly, defects may be generated during the manufacture of the display device. When the thickness t of the transparent organic layer 115 is more than about 50 μm, the transmittance is reduced and the transparent organic layer 115 may bend during hardening. Furthermore, it is difficult to thickly form the transparent organic layer 115, and when the thickness increases, further advantageous effects are not generated.

A gate conductor including a plurality of gate lines (not shown) and a plurality of storage electrode lines (not shown) is formed on the transparent organic layer 115. The gate lines transmit gate signals and include a plurality of gate electrodes 124. The storage electrode lines include a plurality of common electrodes 270 and a plurality of storage electrodes 133. The common electrodes 270 may be formed on the upper substrate 210.

A gate insulating layer 140, a plurality of semiconductor islands 154, a plurality of pairs of ohmic contact islands 163 and 165, a plurality of data lines 171, and a plurality of drain electrodes 175 are sequentially formed on the gate conductor.

The data lines 171 transmit data signals, and include a plurality of source electrodes 173. The drain electrodes 175 are separated from the data lines 171 and are opposite to the source electrodes 173 with respect to the gate electrodes 124.

A gate electrode 124, a source electrode 173, and a drain electrode 175 form a thin film transistor (TFT) together with the semiconductor 154. A channel of the TFT is formed in the semiconductor 154 between the source electrode 173 and the drain electrode 175.

A passivation layer 180 is formed on the exposed semiconductors 154, the data lines 171, the drain electrodes 175, and the gate insulating layer 140. The passivation layer 180 has a plurality of contact holes 185 exposing the drain electrodes 175.

A plurality of pixel electrodes 191 are formed on the passivation layer 180. The pixel electrodes 191 overlap the storage electrodes 133 and do not overlap the common electrode 270. The pixel electrodes 191 are connected to the drain electrodes 175 through the contact holes 185, and receive data voltages from the drain electrodes 175.

The thin film elements such as the above-described thin film transistors are formed on the transparent organic layer 115 and operational defects due to the alkali components and the impurities included in the lower substrate 110 may be avoided.

In the upper panel 200, a light blocking member 220 is formed on the upper substrate 210. The light blocking member 220 overlaps the common electrode 270 and blocks incident light from the outside.

The upper substrate 210 may be made of an alkali-containing glass, and a transparent organic layer made of polyimide may be formed on the upper substrate 210 in this case.

The electrophoretic particles 315 are interposed in the gap between the lower panel 100 and the upper panel 200, and are divided by the partitions 361. The partitions 361 may be fixed on the passivation layer 180 and close to the upper panel 200.

The electrophoretic particles 315 may represent one of red, green, blue, yellow, magenta, cyan, and white, and have a reflective quality.

While exemplary embodiments of the present invention have been described with reference to the figures, it is to be understood that the invention is not limited to the disclosed embodiments, but is intended to cover various modifications and equivalent arrangements.

What is claimed is:

1. A display device comprising:
an alkali-containing glass substrate;
a transparent organic layer contacting the glass substrate; and
a plurality of thin film elements formed on the transparent organic layer.

2. The display device of claim 1, wherein the glass substrate is a soda lime glass substrate.

3. The display device of claim 2, wherein the transparent organic layer has a same transparency as the glass substrate and a refractive index in a range of about 1.5 to about 1.6.

4. The display device of claim 3, wherein the transparent organic layer has a glass transition temperature of about 250° C. to about 450° C.

5. The display device of claim 3, wherein the transparent organic layer includes polyimide.

6. The display device of claim 3, wherein the thickness of the transparent organic layer is in a range of about 0.3 μm to about 50 μm.

7. The display device of claim 3, wherein the sheet resistance of the transparent organic layer is less than about 2×10¹⁷ Ωcm.

8. The display device of claim 3, wherein the thin film elements include a thin film transistor.

9. The display device of claim 8, wherein the thin film elements further include an organic light emitting element.

10. The display device of claim 8, further comprising a liquid crystal layer formed on the thin film elements.

11. The display device of claim 8, further comprising an electrophoretic active layer formed on the thin film elements.

12. The display device of claim 1, wherein the thin film elements include a color filter.

13. A liquid crystal display device comprising:
a first panel including a first substrate having pixel electrodes, thin film transistors and signal lines thereon;
a second panel including a second substrate having a common electrode, at least one color filter, and at least one light blocking member; and
a liquid crystal layer disposed between the first panel and the second panel,
wherein at least one of the first and the second substrates is an alkali-containing glass substrate, and the at least one alkali-containing glass substrate has a transparent organic layer contacting therewith.

14. The liquid crystal display device of claim 13 wherein the alkali-containing glass substrate is a soda lime glass substrate.

15. The display device of claim 14, wherein the transparent organic layer has a same transparency as the alkali-containing glass substrate and a refractive index in a range of about 1.5 to about 1.6.

16. The display device of claim 15, wherein the transparent organic layer has a glass transition temperature of about 250° C. to about 450° C.

17. The display device of claim 15, wherein the organic layer includes polyimide.

18. The display device of claim 15, wherein the thickness of the transparent organic layer is in a range of about 0.3 μm to about 50 μm.

19. The display device of claim 15, wherein the sheet resistance of the organic layer is less than about 2×10¹⁷ Ωcm.

20. An organic light emitting device comprising:
a first substrate including alkali-containing glass; and
a transparent organic layer including polyimide formed on the substrate; wherein
the transparent organic layer has the same transparency as the first substrate, and a refractive index in a range of about 1.5 to about 1.6.

21. The display device of claim 20, wherein the transparent organic layer has a glass transition temperature T_{g} of about 250° C. to about 450° C.

22. The organic light emitting device of claim 20, wherein the thickness of the organic layer is in a range of about 0.3 μm to about 50 μm.

23. The organic light emitting device of claim 20, wherein the sheet resistance of the transparent organic layer is in a range of about 1×10¹⁷ Ωcm to about 2×10¹⁷ Ωcm.
